(19) United States
(12) Patent Application Publication
(10) Pub. No.: US 2026/0180585 A1
(43) Pub. Date: Jun. 25, 2026

(54) FREQUENCY SYNTHESIZER

(71) Applicant: NIHON DEMPA KOGYO CO., LTD., Tokyo (JP)

(72) Inventor: Tsukasa KOBATA, Saitama (JP)

(73) Assignee: NIHON DEMPA KOGYO CO., LTD., Tokyo (JP)

(21) Appl. No.: 19/428,344

(22) Filed: Dec. 22, 2025

(30) Foreign Application Priority Data
Dec. 24, 2024 (JP) 2024-227821

(51) Int. Cl. H03L 7/093; H03L 7/099

(52) U.S. Cl. CPC H03L 7/093; H03L 7/099

(57) ABSTRACT

A frequency synthesizer includes a voltage controlled oscillator, an analog-to-digital converter, a first processing unit and a second processing unit, an adder, a digital-to-analog converter, a monitoring unit, and a switching unit. The first processing unit and a second processing unit output a first digital signal and a second digital signal for frequency adjustment corresponding to a phase difference, respectively. The adder outputs an addition signal obtained by adding the output from the first processing unit to the output from the second processing unit to a downstream stage. The switching unit switches a first state in which only the first digital signal among the first digital signal and the second digital signal is supplied to the adder to a second state in which the second digital signal and the first digital signal as a fixed value are each supplied to the adder, based on a parameter.

### CROSS-REFERENCE TO RELATED APPLICATIONS

This application is based on and claims priority under 35 U.S.C. § 119 to Japanese Patent Application No. 2024-227821, filed on December 24, 2024, the entire content of which is incorporated herein by reference.

### TECHNICAL FIELD

This disclosure relates to a frequency synthesizer.

### DESCRIPTION OF THE RELATED ART

A frequency synthesizer that forms a Phase Locked Loop (PLL) by feeding back an output of a voltage controlled oscillator has been known. There is a frequency synthesizer that digitally processes and controls an output of a control voltage to the voltage controlled oscillator upon forming the PLL. In such a frequency synthesizer, the oscillation output of the voltage controlled oscillator is converted into a digital signal by an analog-to-digital converter and retrieved in a digital processing circuit, and undergoes a phase comparison with a reference frequency signal. This comparison result is output as an analog signal via a digital-to-analog converter, and thus, the above-described control voltage is generated. Japanese Patent No. 4843704 discloses one example of such a frequency synthesizer.

A need thus exists for a frequency synthesizer which is not susceptible to the drawback mentioned above.

### SUMMARY

According to an aspect of this disclosure, there is provided a frequency synthesizer including a voltage controlled oscillator, an analog-to-digital converter, a first processing unit and a second processing unit, an adder, a digital-to-analog converter, a monitoring unit, and a switching unit. The voltage controlled oscillator outputs a frequency signal corresponding to a control voltage. The analog-to-digital converter digitalizes a frequency signal corresponding to the output of the voltage controlled oscillator. The first processing unit and a second processing unit, in order to process the digitalized frequency signal to cancel a phase difference between the frequency signal and a reference frequency signal, output a first digital signal and a second digital signal for frequency adjustment corresponding to the phase difference, respectively. The adder outputs an addition signal obtained by adding the output from the first processing unit to the output from the second processing unit to a downstream stage. The digital-to-analog converter is disposed to be shared by the first processing unit and the second processing unit in downstream stage of the adder, and converts an input signal to analog and outputs the input signal to generate the control voltage. The monitoring unit monitors a parameter that changes according to a change in the frequency signal corresponding to the control voltage. The switching unit switches a first state in which only the first digital signal among the first digital signal and the second digital signal is supplied to the adder to a second state in which the second digital signal and the first digital signal as a fixed value are each supplied to the adder, based on the parameter.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a block diagram of a frequency synthesizer according to one embodiment of the disclosure;

FIG. 2 is a block diagram illustrating a part of the frequency synthesizer in more detail;

FIG. 3 is a block diagram illustrating switching of switches of the frequency synthesizer; and

FIG. 4 is a block diagram of a frequency synthesizer according to a comparative example.

### DETAILED DESCRIPTION

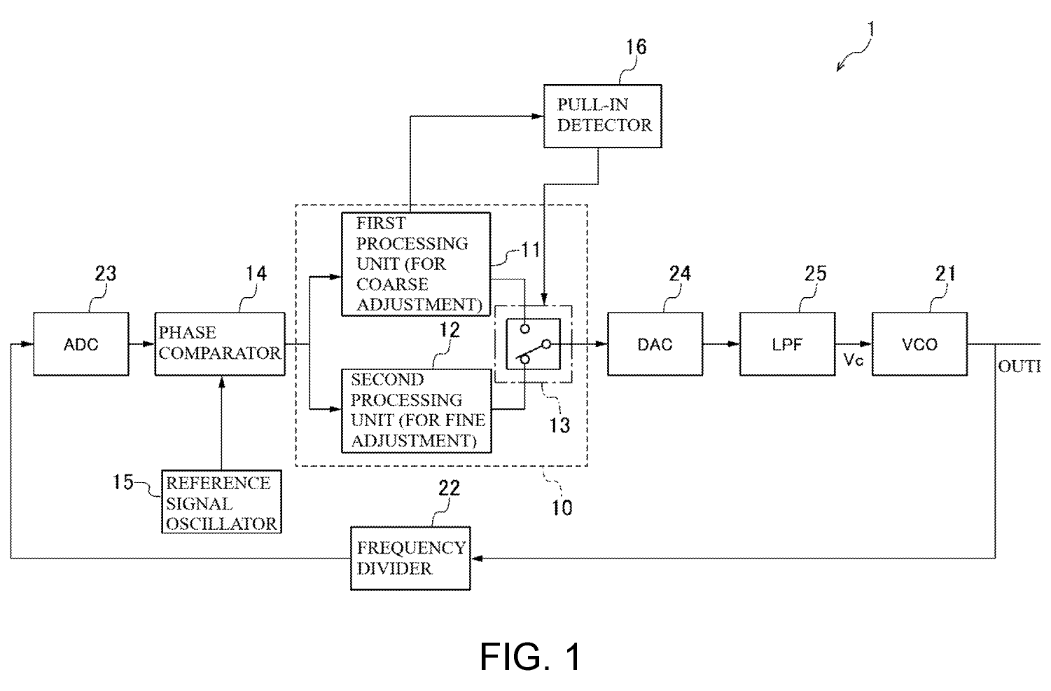

A schematic configuration of a frequency synthesizer 1 as one embodiment of the present disclosure will be described with reference to a block diagram in FIG. 1. The frequency synthesizer 1 includes a voltage controlled oscillator (VCO) 21 that forms a PLL so as to output an oscillation signal synchronized with an input signal, and increases an output frequency fout according to an increase of a supplied control voltage Vc. The output of the VCO 21 is an output of the frequency synthesizer 1.

The control voltage Vc generated based on a phase difference between a reference frequency corresponding to a set frequency of the frequency synthesizer 1 set by a user and a frequency specified by a signal obtained by dividing and digitalizing a feedback signal, which is a fed-back output signal of the VCO 21, is supplied to an input side of the VCO 21, and thus, the output frequency fout of the VCO 21 is feedback controlled. When the frequency of the above-described divided signal and the reference frequency match, the output frequency fout is locked to the set frequency. Until this output frequency fout is locked, a circuit used for generating the control voltage Vc is switched in a processing unit 10 that performs the digital process of the frequency synthesizer 1.

This processing unit 10 will be schematically described. The processing unit 10 includes a first processing unit 11 for coarse adjustment that relatively promptly increases the output frequency fout of the VCO 21 and performs pull-in of the output frequency fout toward the set frequency, and a second processing unit 12 for fine adjustment for matching the output frequency fout with the set frequency. When the user performs a predetermined operation from an operation unit (not illustrated) to instruct an operation start of the frequency synthesizer 1, the first processing unit 11 forms a loop of the above-described feedback control first, and the second processing unit 12 forms a loop of the control next. Note that the processing unit 10 includes a selection unit 13 for switching the loops.

The frequency synthesizer 1 includes an analog-to-digital converter (ADC) 23, a digital-to-analog converter (DAC) 24, a low-pass filter (LPF) 25, a phase comparator 14, a reference signal oscillator 15, and a pull-in detector 16 for detecting an pull-in state of the above-described frequency, besides the above-described VCO 21, a frequency divider 22 that divides the output frequency of the feedback signal of the VCO 21 by a division ratio of 1/N (N is an integer of 1 or more), and the processing unit 10. The reference signal oscillator 15 is constituted of, for example, a direct digital synthesizer (DDS), and outputs a digital signal (a reference frequency signal) corresponding to the reference frequency.

An analog signal divided by the frequency divider 22 is output to the ADC 23. The ADC 23 samples the analog signal by a clock signal supplied from a clock signal source (not illustrated), and outputs the sampling value as a digital signal to the phase comparator 14. The phase comparator 14 outputs a signal (a rotational vector V described below) corresponding to a phase difference between a frequency specified by this digital signal and a reference frequency of a reference frequency signal output from the reference signal oscillator 15.

The processing unit 10 is disposed downstream of the phase comparator 14, and the first processing unit 11 and the second processing unit 12 respectively act such that the phase difference between the frequencies in the above-described signals input to the phase comparator 14 is cancelled. Downstream of the first processing unit 11 and the second processing unit 12, the selection unit 13, the DAC 24, and the LPF 25 are disposed in this order. Accordingly, the DAC 24 and the LPF 25 are in a configuration of being shared by the first processing unit 11 and the second processing unit 12.

The digital signal output from the processing unit 10 is converted into an analog signal by the DAC 24, and is output to the LPF 25. The output voltage from the LPF 25 is input as the control voltage Vc to the VCO 21. Since noise is likely to be included in a relatively high frequency band among the frequency signals supplied from the DAC 24, the LPF 25 is disposed to cut that frequency band. The cutoff frequency of the LPF 25 is, for example, 100 kHz or more, specifically, for example, 250 kHz.

The output signal from the first processing unit 11 is also input to the frequency pull-in detector 16. Based on a detection result by the pull-in detector 16, control loops are switched via the selection unit 13. Note that, since FIG. 1 is a schematic diagram, the signal of the first processing unit 11 is illustrated not to be input to the downstream stage when the loop is formed by the second processing unit 12, but in practice, it is input as described later.

The processing unit 10, the phase comparator 14, and the pull-in detector 16 are configured as a digital processing unit implemented by, for example, a field programmable gate array (FPGA), which performs digital processing. Besides the ADC 23 described above, this digital processing unit and the DAC 24 also operate on a clock signal supplied from the clock source.

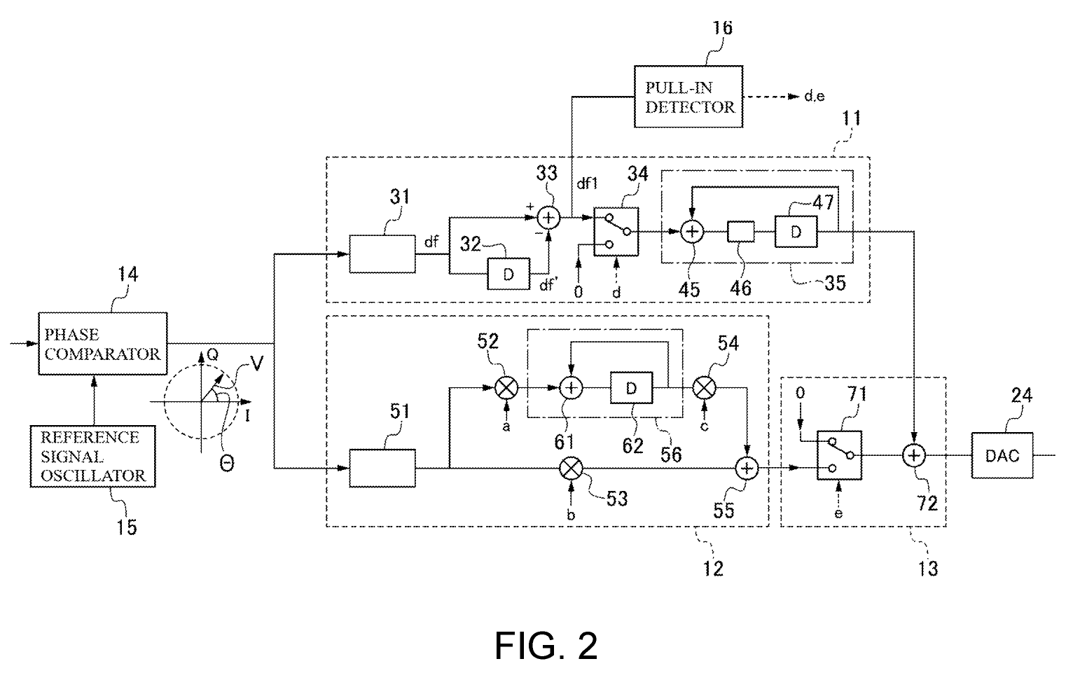

The following further describes the phase comparator 14 and the processing unit 10 with reference to the block diagram in FIG. 2. The phase comparator 14 extracts the rotational vector V having a predetermined length A and a rotation angle θ from the respective signals input from the reference signal oscillator 15 and the ADC 23, and outputs the rotational vector V to the processing unit 10. This rotational vector V is schematically illustrated in FIG. 2. On the orthogonal coordinate plane illustrated in FIG. 2, the I-axis as a horizontal axis represents a real part of the rotational vector V, and the Q-axis as a vertical axis represents an imaginary part of the rotational vector V.

When the difference between the reference frequency and the frequency specified by the signal output from the ADC 23 is assumed to be an error frequency df, the rotation angle θ of the rotational vector V is a parameter that changes by the error frequency df, and the rotation angle θ is 0 when the error frequency df is 0. The outputs from the first processing unit 11 and the second processing unit 12 are controlled such that the rotation angle θ becomes 0. This extraction of the rotational vector V is performed as described in, for example, Japanese Unexamined Patent Application Publication No. 2007-74291. That is, a sine wave signal specified by the output signal from the ADC 23 undergoes a quadrature detection by a sine wave signal specified by the reference frequency signal, and furthermore, is passed through the low-pass filter, and thus, a value of the real part and a value of the imaginary part of the rotational vector V are obtained.

Subsequently, the first processing unit 11 will be described. The first processing unit 11 includes a frequency difference detector 31, a delay circuit 32, an adder 33, a first switch 34, and a first integrating circuit 35. The frequency difference detector 31 includes a delay circuit. This delay circuit outputs data held in a register to the downstream stage. The above-described held data is updated to data to be input to the delay circuit every cycle of the frequency of the clock signal, and therefore, this data to be input to the delay circuit is output to the downstream stage with one clock cycle delay. Note that the input data is output with the one clock cycle delay to another delay circuit in the subsequent description as well similarly to this delay circuit of the frequency difference detector 31.

In the frequency difference detector 31, a predetermined operation is performed by using the rotational vector V newly supplied to the frequency difference detector 31 and the rotational vector V obtained by the above-described delay circuit with the one clock cycle delay with respect to the above-described rotational vector V, and thus, the error frequency df is obtained.

The error frequency df is input to each of the delay circuit 32 and the adder 33 arranged downstream of the frequency difference detector 31. The signal output from the delay circuit 32 is also input to the adder 33. In the adder 33, the frequency output from the delay circuit 32 (referred to as the error frequency df’) is sign-inverted and then added to the error frequency df input from the frequency difference detector 31, and the resulting value, which is the amount of error frequency variation df1 (= df − df’), is output downstream. In this way, the amount of error frequency variation df1 becomes the difference between the error frequency df obtained at the n-th sampling and the error frequency df obtained at the (n−1)-th sampling.

The first switch 34 switches to selectively output either the above-described amount of error frequency variation df1 or a constant supplied from a parameter supply unit (not illustrated) (that is, a preliminarily set signal) to the first integrating circuit 35. This predetermined constant is 0. This switching of the first switch 34 is performed in synchronization with switching of a second switch 71 described below in the selection unit 13. When the first processing unit 11 is used as a loop of the feedback control, the output from the adder 33 is supplied to the first integrating circuit 35, and when the second processing unit 12 is used as the loop, the switching of the first switch 34 is performed so as to supply 0 as the constant to the first integrating circuit 35.

The first integrating circuit 35 includes a first adder 45, a saturation processing circuit 46, and a delay circuit 47, and these respective units are disposed in this order toward the downstream stage. The output of the delay circuit 47 is input to the selection unit 13 as a first digital signal, and is fed back to the first adder 45. The first adder 45 adds a frequency value of the signal thus fed back to a frequency value of the signal supplied via the first switch 34, and this additional value is input to the saturation processing circuit 46.

The saturation processing circuit 46, when the input value is smaller than a predetermined lower limit value, outputs the lower limit value, when the input value is greater than a predetermined upper limit value, outputs the upper limit value, and when the input value is equal to or more than the lower limit value and equal to or less than the upper limit value, outputs a signal about the input value to the delay circuit 47. Accordingly, the saturation processing circuit 46 is a selection output unit that selects and outputs one of the output signal from the first adder 45 and the preliminarily set signal. By including such a saturation processing circuit 46, the first integrating circuit 35 contributes to prompt pull-in of a frequency by keeping the input value to the delay circuit 47 within a predetermined range, in addition to smoothing outputting to the downstream stage.

The amount of error frequency variation df1 as the output of the adder 33 of the first processing unit 11 described above is also supplied to the pull-in detector 16. The pull-in detector 16 is configured as a monitoring unit that monitors this amount of error frequency variation df1 and compares the amount of error frequency variation df1 with a threshold value. When the amount of error frequency variation df1 is determined to exceed the threshold value from the result of this comparison, the pull-in detector 16 outputs the signal for switching the first switch 34 and the second switch 71.

Subsequently, the second processing unit 12 will be described. This second processing unit 12, which forms the loop filter of the PLL circuit, includes an imaginary part extractor 51, multipliers 52 to 54 for adjusting a loop gain of the filter, a second adder 55, and a second integrating circuit 56. The imaginary part extractor 51 outputs a value of the imaginary part of the rotational vector V to the multipliers 52, 53. Note that the reason of thus outputting the value of the imaginary part to the downstream stage is, since when the second processing unit 12 forms a control loop, the phase difference between the output frequency from the ADC 23 and the reference frequency is in a reduced state due to the pull-in of the frequency by the first processing unit 11, and the imaginary part represents the phase difference in such a state where the phase difference is reduced.

There are the second integrating circuit 56 and the second adder 55 disposed in the respective downstream stages of the multipliers 52, 53. There is the multiplier 54 disposed in downstream of the second integrating circuit 56, and the output of the multiplier 54 is input to the second adder 55. Besides the output from the imaginary part extractor 51, a constant (that is, a preliminarily set signal) is input to the multipliers 52, 53, and the multipliers 52, 53 output a multiplication value of these input values to the downstream stages. Besides the output value from the second integrating circuit 56, the constant is input to the multiplier 54, and the multiplier 54 outputs a multiplication value of these input values to the downstream stage.

The second integrating circuit 56 includes an adder 61 and a delay circuit 62 disposed downstream of the adder 61, and the output of the delay circuit 62 is fed back to the adder 61. The adder 61 adds the value thus fed back to the output value from the multiplier 52, and the added value is output to the delay circuit 62. The second adder 55 adds the output values from the multipliers 53, 54 together, and a signal of the added value is output to the selection unit 13 as a second digital signal. While it is not illustrated, there is disposed a circuit to reset the value held in the delay circuit 62. This resetting is performed at a timing where the first switch 34 and the second switch 71 operate such that the state where the first processing unit 11 forms a loop is formed.

Subsequently, the selection unit 13 will be described. The selection unit 13 is constituted of the second switch 71 and an adder 72 disposed downstream of the second switch 71. The second switch 71 constitutes a switching unit for switching control loops together with the above-described first switch 34, and switches so as to selectively output any one of the output from the second adder 55 of the second processing unit 12 or the constant (that is, the preliminarily set signal) supplied from the parameter supply unit (not illustrated) to the adder 72 downstream. This constant is, for example, 0.

The adder 72 adds a signal value supplied via the second switch 71 to a signal value from the first integrating circuit 35 of the first processing unit 11, and outputs a signal of the added value (an addition signal) to the DAC 24. A voltage signal corresponding to the addition signal is output from the DAC 24.

An operation of the frequency synthesizer 1 described above will be described. When an instruction of a predetermined operation start is instructed via an operation unit (not illustrated) after a set frequency is input by the user, a first state in which the constant 0 is output to the adder 72 via the second switch 71 of the selection unit 13, and an output from the adder 33 is input to the first integrating circuit 35 via the first switch 34 of the first processing unit 11 is obtained. FIG. 2 described above illustrates this first state. Additionally, the operations of the first switch 34 and the second switch 71 are thus controlled in one hand, a value held onto the delay circuit 62 in the second integrating circuit 56 of the second processing unit 12 is reset.

As described above, the first processing unit 11 forms a loop of the feedback control of the output frequency fout of the VCO 21, and the output corresponding to the rotational vector V generated by the phase comparator 14 is supplied to the adder 72. The other input to the adder 72 by the second switch 71 is 0 as described above, and therefore, the output of the adder 72 is the same as the output of the first processing unit 11 and is supplied to the DAC 24. The control voltage Vc corresponding to the output to the DAC 24 is applied to the VCO 21.

Such formation of the control loop by the first processing unit 11 allows for obtainment of an oscillation output of the VCO 21, and meanwhile, the pull-in detector 16 determines whether the amount of error frequency variation df1 as an output from the adder 33 exceeds the threshold value or not. When the threshold value is determined not to be exceeded, the states of the first switch 34 and the second switch 71 are maintained. That is, the formation of the control loop by the first processing unit 11 is maintained. The control voltage Vc supplied to the VCO 21 is increased by the action of the first processing unit 11, and the output frequency fout is increased and the pull-in of the output frequency fout to the set frequency progresses.

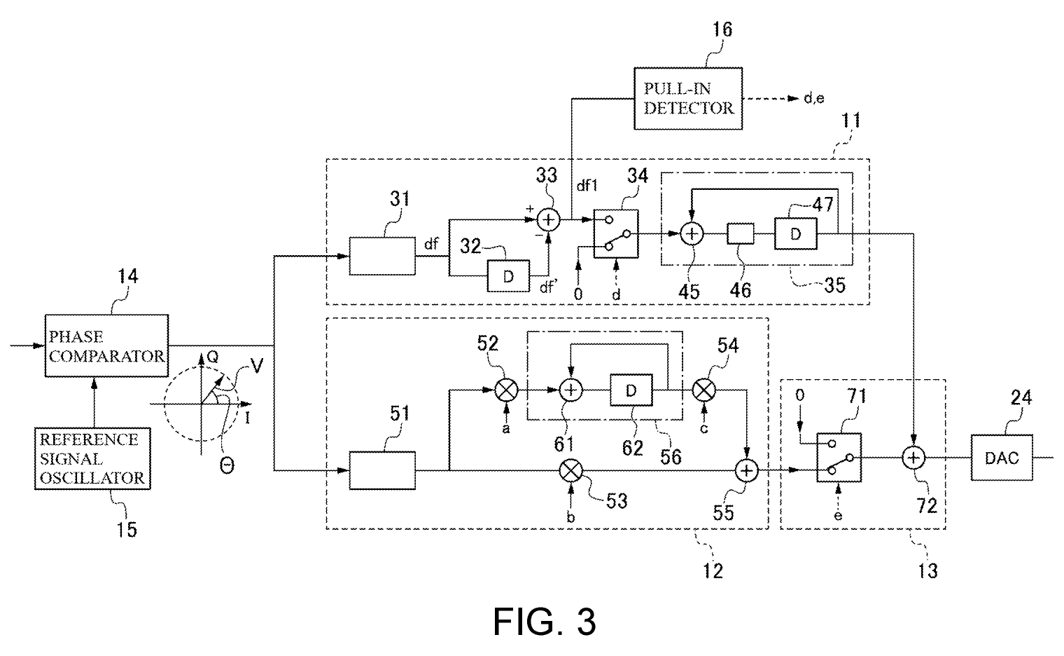

The error frequency df is gradually decreased as the pull-in progresses, and when the amount of error frequency variation df1 is determined to exceed the threshold value by the pull-in detector 16, the first switch 34 and the second switch 71 are switched. Specifically, as illustrated in FIG. 3, a second state in which the second switch 71 supplies the output from the second adder 55 of the second processing unit 12 instead of the constant 0 to the adder 72 of the selection unit 13, and the first switch 34 outputs the constant 0 instead of the output from the adder 33 to the first integrating circuit 35 is obtained.

In this second state, the constant 0 is input to the first adder 45 that constitutes the first integrating circuit 35 of the first processing unit 11, which makes the output from the first adder 45 constant. Accordingly, the output from the first integrating circuit 35, that is, the first processing unit 11 to the adder 72 is maintained to the output at the time of switching to the second state. The output corresponding to the rotational vector V is supplied to the adder 72 from the second processing unit 12, and is added to the output from the first processing unit 11. The added output is supplied to the DAC 24, and the control voltage Vc corresponding to the output to the DAC 24 is applied to the VCO 21. Accordingly, a loop of the feedback control is formed by the second processing unit 12 instead of the first processing unit 11. The output frequency fout approaches the set frequency due to the action of this second processing unit 12, and eventually matches with the set frequency and is locked.

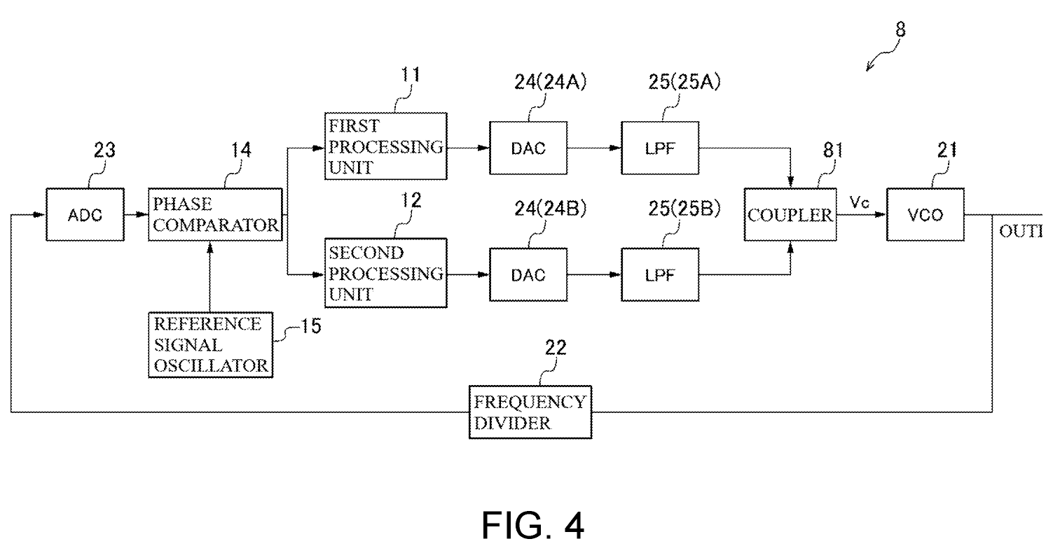

To indicate advantages of the frequency synthesizer 1 described above, a configuration of a frequency synthesizer 8 of a comparative example will be described focusing on differences from the frequency synthesizer 1 with reference to FIG. 4. In the frequency synthesizer 8, the selection unit 13 and the pull-in detector 16 are not disposed, the respective DACs 24 are disposed in downstream of the first processing unit 11 and the second processing unit 12, and the LPFs 25 are disposed in downstream of the respective DACs 24.

Hereinafter, the DAC 24 and the LPF 25 in downstream of the first processing unit 11 are described as a DAC 24A and an LPF 25A, and the DAC 24 and the LPF 25 in downstream of the second processing unit 12 are described as a DAC 24B and an LPF 25B in some cases. Respective outputs from the LPF 25A and the LPF 25B are input to a coupler 81, and the coupler 81 applies a voltage corresponding to the sum of each of these outputs as the control voltage Vc to the VCO 21. The first processing unit 11 of the frequency synthesizer 8 does not include the first switch 34, and the output of the adder 33 in the first processing unit 11 is directly input to the first integrating circuit 35.

This frequency synthesizer 8 has a configuration in which the DAC 24 and the LPF 25 are disposed accompanying each of the first processing unit 11 and the second processing unit 12, and therefore, the manufacturing cost may be relatively high. From another point of view, the frequency synthesizer 1 in which the DAC 24 and the LPF 25 are shared by each of the first processing unit 11 and the second processing unit 12 allows for a reduced manufacturing cost. The frequency synthesizer 1 is preferred also from a perspective of reduced power consumption during operation because the number of the DAC 24 and the LPF 25 is less.

Also in the frequency synthesizer 8, the second processing unit 12 also has a role of performing a fine control of the output frequency fout, similarly to the frequency synthesizer 1. Therefore, for the DAC 24B accompanying the second processing unit 12, it is required to use a DAC with a relatively satisfactory phase noise characteristic, but for the DAC 24A accompanying the first processing unit 11 that performs coarse adjustment, it is not required to use a DAC with a satisfactory phase noise characteristic as satisfactory as the DAC 24B. Therefore, it is considered that a DAC with an inferior phase noise characteristic to that of the DAC 24B is used for the DAC 24A for the purpose of reducing the manufacturing cost of the frequency synthesizer 8.

However, in such a case, to reduce the noise included in the output of the VCO 21 after the output frequency fout of the VCO 21 is locked, the cutoff frequency of the LPF 25A needs to be a relatively low value, for example, approximately several hundred Hz. When the cutoff frequency of the LPF 25A is thus lowered, the increase of the control voltage Vc supplied to the VCO 21 after the user instructs an operation start is suppressed, and therefore, a speed of the pull-in of the output frequency fout to the set frequency is slowed down, and the period it takes from the instruction of the operation start to the lock of the output frequency fout is increased. As described above, the frequency synthesizer 8 may be difficult to reduce the manufacturing cost down to a desired cost while reducing a period it takes to lock this output frequency fout.

On the other hand, the frequency synthesizer 1 needs only one DAC 24, and a DAC with a satisfactory phase noise characteristic is used for the DAC 24. When the DAC 24 thus has the satisfactory phase noise characteristic, the noise is difficult to be mixed into the output frequency fout after being locked to the set frequency even though the cutoff frequency of the LPF 25 in the downstream stage is relatively low. Therefore, the cutoff frequency is a relatively high value as exemplarily indicated, and the speed of the pull-in of the output frequency fout to the set frequency can be made relatively large. From the above, the frequency synthesizer 1 allows for reducing the manufacturing cost while reducing the period it takes to lock the output frequency fout.

The switching of the first switch 34 and the second switch 71 is not limited to monitor the amount of error frequency variation df1 described above, and may be performed by monitoring a parameter that changes according to the change of the output frequency fout from the VCO 21 other than that. Specifically, for example, the first switch 34 and the second switch 71 may be switched based on the threshold value and the comparison by monitoring the output value from the ADC 23, or the error frequency df may be monitored.

While the above-described second processing unit 12 has a configuration in which the output from the imaginary part extractor 51 is supplied to each of a system (an integrating system) including the integrating circuit 56 and a system (a direct system) that includes only the multiplier 53 without the integrating circuit 56 disposed, and the second adder 55 adds the outputs of the integrating system and the direct system together and outputs it, it is only necessary that, corresponding to the phase difference between the reference frequency and the frequency of the output signal from the ADC 23, the second processing unit 12 can output a signal for cancelling this phase difference to the downstream stage. Therefore, the configuration is not limited to such a configuration, and, for example, may be a configuration including only one of the direct system or the integrating system.

Note that the above-described rotational vector V, the error frequency df and the amount of error frequency variation df1 calculated from the rotational vector V, and the imaginary part of the rotational vector V input to the second processing unit 12 correspond to the signal corresponding to the phase difference between the reference frequency and the frequency of the output signal from the ADC 23. Since the reference frequency corresponds to the set frequency, these rotational vector V and the like are also a signal corresponding to the phase difference between the set frequency and the frequency of the output signal from the ADC 23.

The embodiment disclosed this time is illustrative in every point and should be considered not to be restrictive. The above-described embodiment may be omitted, replaced, changed, and combined in various manners without departing from accompanying claims and their spirits.

### Evaluation Test

Evaluations regarding phase noise characteristics were performed for the frequency synthesizer 1 described in FIG. 1 and the frequency synthesizer 8 described in FIG. 4. Upon performing the evaluations, the division ratio of the frequency divider 22 was set to 1, and the set frequency was set to 950 MHz in the frequency synthesizers 1, 8. Note that the respective cutoff frequencies of the LPF 25 of the frequency synthesizer 1 and the LPF 25B of the frequency synthesizer 8 are 250 kHz as exemplarily indicated in the embodiment, and the cutoff frequency of the LPF 25A of the frequency synthesizer 8 is several hundred Hz. The measurements under such settings resulted in the phase noise characteristic of approximately −130 dBc/Hz in each of the frequency synthesizers 1, 8.

In addition, a period it takes from the power on till the output of the set frequency (a period it takes to lock the output frequency fout) was also measured for the frequency synthesizers 1, 8. It was 200 msec in the frequency synthesizer 8, whereas it was 200 μ second in the frequency synthesizer 1. Accordingly, this evaluation test indicated that the frequency synthesizer 1 allows for reduction in the period it takes to lock the output frequency fout without reducing the phase noise characteristic compared with the frequency synthesizer 8.

With the frequency synthesizer according to the embodiment, a manufacturing cost is reducible while reducing a period it takes to obtain an output of a set frequency.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A frequency synthesizer comprising:
a voltage controlled oscillator that outputs a frequency signal corresponding to a control voltage;
an analog-to-digital converter that digitalizes a frequency signal corresponding to the output of the voltage controlled oscillator;
a first processing unit and a second processing unit that, in order to process the digitalized frequency signal to cancel a phase difference between the frequency signal and a reference frequency signal, output a first digital signal and a second digital signal for frequency adjustment corresponding to the phase difference, respectively;
an adder that outputs an addition signal obtained by adding the output from the first processing unit to the output from the second processing unit, to a downstream stage;
a digital-to-analog converter that is disposed to be shared by the first processing unit and the second processing unit in downstream stage of the adder, and converts an input signal to analog and outputs the input signal to generate the control voltage;
a monitoring unit that monitors a parameter that changes according to a change in the frequency signal corresponding to the control voltage; and
a switching unit that switches from a first state in which only the first digital signal among the first digital signal and the second digital signal is supplied to the adder to a second state in which the second digital signal and the first digital signal set to a fixed value are each supplied to the adder, based on the parameter.

2. The frequency synthesizer according to claim 1, wherein
the first processing unit includes:
a first integrating circuit; and
a first switch that forms the switching unit, the first switch switching so that a signal corresponding to the phase difference is input to the first integrating circuit in the first state and a preliminarily set signal is input to the first integrating circuit in the second state, wherein
the frequency synthesizer further comprises a second switch constituting the switching unit disposed between the adder and the second processing unit, the second switch switching so that a preliminarily set signal is input to the adder in the first state and a signal from the second processing unit is input to the adder in the second state.

3. The frequency synthesizer according to claim 2, wherein
the first integrating circuit includes:
a delay circuit;
a first adder that is disposed upstream of the delay circuit and receives a fed-back output signal of the delay circuit; and
a selective output unit disposed between the first adder and the delay circuit, the selective output unit outputting one of an output signal from the first adder and the preliminarily set signal to the delay circuit according to the output signal from the first adder.

4. The frequency synthesizer according to claim 3, further comprising:
a low-pass filter interposed between the digital-to-analog converter and the voltage controlled oscillator, wherein
the low-pass filter has a cutoff frequency of 100 kHz or more.
